(19) United States
(12) Patent Application Publication
(10) Pub. No.: US 2025/0156622 A1
(43) Pub. Date: May 15, 2025

(54) PROCESS OF FITTING FUNCTION PARAMETERS THAT FACILITATES ACCURATE PATTERN-BASED 3D CAPACITANCE EXTRACTION

(71) Applicant: International Business Machines Corporation, Armonk, NY (US)

(72) Inventors: David J. Widiger, Pflugerville, TX (US); Ronald Dennis Rose, Essex Junction, VT (US); Steven Joseph Kurtz, Austin, TX (US); Susan Elizabeth Cellier, Hopewell Junction, NY (US); Lewis William Dewey, III, Wappingers Falls, NY (US)

(21) Appl. No.: 18/507,309

(22) Filed: Nov. 13, 2023

(51) Int. Cl. G06F 30/398; G06F 30/367; G06F 30/392

(52) U.S. Cl. CPC G06F 30/398; G06F 30/367; G06F 30/392

(57) ABSTRACT

A method for analyzing an area of a target wire includes determining a wiring pattern for performing pattern-based 3D capacitance extraction, determining the target wire included in the wiring pattern, and dividing the target wire into segments based on effective spaces of various crossing wires. The method further includes determining a capacitance analysis that applies for each of the segments, determining a plurality of capacitance results corresponding to the capacitance analysis applied to each of the segments, and accumulating the plurality of capacitance results to extract a total capacitance corresponding to the target wire. The segments are based on an effective spacing of crossing wires, which are located above the target wire and extend across the target wire. The effective spaces are determined using a parameterized function that implements at least two adjustable parameters that are set to obtain the wiring pattern using a fitting process.

### BACKGROUND

The present invention relates to the design and manufacture of integrated circuits (ICs), and more specifically, to VLSI designs and devices based on the analysis and optimization of such circuits.

Parasitic capacitance is a feature of any integrated circuit design. Parasitic capacitance occurs when different charges are present on adjacent wires that are separated by dielectric in the back-end-of-line (BEOL) portion of a circuit. The differing charges can momentarily generate voltage between the wires, which can confound the intended scheme of voltages within the circuit and alter the circuit timing. Accordingly, in designing integrated circuits, one aspect is to reduce the parasitic capacitances within the circuit. Preferably, the reduced parasitic capacitances could be achieved in the design stage before a prototype circuit is fabricated.

### SUMMARY

According to a non-limiting embodiment, a method for analyzing an area of a target wire includes determining a wiring pattern for performing pattern-based 3D capacitance extraction, determining the target wire included in the wiring pattern, and dividing the target wire into segments based on effective spaces of various crossing wires. The method further includes determining a capacitance analysis that applies for each of the segments, determining a plurality of capacitance results corresponding to the capacitance analysis applied to each of the segments, and accumulating the plurality of capacitance results to extract a total capacitance corresponding to the target wire. The segments are based on an effective spacing of crossing wires included in the wiring pattern, which are located above the target wire and extend across the target wire. The effective spaces of the various crossing wires are determined using a parameterized function that implements at least two adjustable parameters that are set to obtain the wiring pattern using a fitting process.

According to another non-limiting embodiment, a computing system comprises a memory, and at least one processor, coupled to said memory. Then processor is operative to perform operations comprising determine a wiring pattern for performing pattern-based 3D capacitance extraction, determine a target wire included in the wiring pattern, and divide the target wire into segments based on effective spaces of the various crossing wires. The operations further comprises determine a capacitance analysis that applies for each of the segments, determine a plurality of capacitance results corresponding to the capacitance analysis applied to each of the segments, and accumulate the plurality of capacitance results to extract a total capacitance corresponding to the target wire. The segments are based on an effective spacing of crossing wires included in the wiring pattern, which are located above the target wire and extend across the target wire. The effective spaces of the various crossing wires are determined using a parameterized function (f(s)) that implements at least two adjustable parameters that are set to obtain the wiring pattern using a fitting process.

According to a non-limiting embodiment, a computer program product to control a computer system to perform a pattern-based 3D capacitance extraction perform a pattern-based 3D capacitance extraction. The computer program product comprises a computer readable storage medium having program instructions embodied therewith. The program instructions executable by an electronic computer processor to control the computer system to perform operations comprising determine a wiring pattern for performing pattern-based 3D capacitance extraction, determine a target wire included in the wiring pattern, and divide the target wire into segments based on effective spaces of the various crossing wires. The operations further comprise determine a capacitance analysis that applies for each of the segments, determine a plurality of capacitance results corresponding to the capacitance analysis applied to each of the segments, and accumulate the plurality of capacitance results to extract a total capacitance corresponding to the target wire. The segments are based on an effective spacing of crossing wires included in the wiring pattern, which are located above the target wire and extend across the target wire. The effective spaces of the various crossing wires are determined using a parameterized function (f(s)) that implements at least two adjustable parameters that are set to obtain the wiring pattern using a fitting process.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the present disclosure are apparent from the following detailed description taken in conjunction with the accompanying drawings in which:

FIG. 1 depicts a block diagram of an example computer system for use in conjunction with one or more embodiments of the present invention;

FIG. 2 illustrates a side view of a portion of a target net of a VLSI design according to a non-limiting embodiment of the present disclosure;

FIG. 3 illustrates segmentation for the portion of the target net of FIG. 2 based on four defined relationships, in accordance with an example embodiment;

FIG. 4 illustrates a target net having metal directly above, metal directly below, and left and right neighbor nets to either side on the same layer according to a non-limiting embodiment of the present disclosure;

FIG. 5 illustrates the fringe capacitance for a target net according to a non-limiting embodiment of the present disclosure;

FIG. 6 illustrates a top-view of a target net having two neighbor nets on the same layer according to a non-limiting embodiment of the present disclosure;

FIG. 7 illustrates a side-view of target area with cross-sectional views of the neighbor nets on the two layers above and the two layers below the target net according to a non-limiting embodiment of the present disclosure;

FIG. 8 illustrates the configuration of FIG. 7 where each original spacing has been modified to derive the effective spacing se based on an effective spacing function return value according to a non-limiting embodiment of the present disclosure;

FIG. 9 depicts typical BEOL wiring according to a non-limiting embodiment of the present disclosure;

FIG. 10 is a flow diagram illustrating a method of determining a 3D wiring pattern that can be used to perform a pattern-based 3D capacitance extraction according to a non-limiting embodiment of the present disclosure;

FIG. 11 is a flow diagram illustrating a method for analyzing an area of a target wire using an optimal fitted parameterized function according to a non-limiting embodiment of the present disclosure;

FIG. 12 is a flow diagram illustrating a method for performing an iterative parameter fitting process is illustrated according to a non-limiting embodiment of the present disclosure;

FIG. 13 depicts an exemplary high-level Electronic Design Automation (EDA) tool flow, within which aspects of the present disclosure can be employed; and

FIG. 14 depicts a flow diagram of a design process used in semiconductor design, manufacture, and/or test according to a non-limiting embodiment of the present disclosure.

### DETAILED DESCRIPTION

In VLSI (very large-scale integration) digital design, fabricated devices conventionally include millions of transistors implementing hundreds of storage devices, functional logic circuits, and the like. The designs are often segmented or partitioned into sub-blocks (such as cores, units, macros, sub-hierarchies, and the like) to make the design process more manageable. For example, the design, placement, and routing of the circuits may be conducted at both a high-level and sub-block level, where the high-level considers the complete device including all sub-blocks (known as in-context design) and the sub-block level considers the design of a single sub-block (known as out-of-context design). While a sub-block level design may be used in multiple instances within the device, conventionally, only a single version of the design of the sub-block is produced.

Timing analysis and timing considerations for a sub-block conventionally include constraints, such as the specification of the arrival time (AT) for each input signal at the entry of the sub-block and the speciation of a required arrival time (RAT) for generating each output signal of the sub-block. The required arrival time must consider the propagation delay through the circuit, including the slew rate of the output signal. The propagation delays, slew rates, and the like are influenced by capacitive loads, including the capacitive effects experienced by signals propagating through metal wires (nets) of the VLSI device.

So-called 2.5D (2.5-dimensional) is a capacitive analysis technique that is fast compared to 3D capacitance analysis methods. Designers look to 2.5D as a solution to increasing macro sizes, larger cores and flat chips, and the desire for better performance in the construction phases of a design where speed is necessary. To simplify the analysis of such designs, 2.5D often makes gross assumptions about the wires above and below a target net during timing analysis. Some techniques replace all metal in layers above and below the target net by simple densities, with one density value per layer, regardless of the actual wire density directly above and below the target wire. Other techniques require all wires to exist on a strict gridded structure and make limiting assumptions about wires over and under a net. While 2.5D methods utilized in the industry provide speedup, the simplifying assumptions degrade accuracy too significantly for current techniques to be useful for, e.g., 7 nanometer (nm) designs. 2.5D refers to a capacitive analysis technique that is fast compared to 3D capacitance analysis methods.

The present disclosure describes one or more non-limiting embodiments, which provide a system and process of fitting function parameters that facilitate improved accuracy of a pattern-based 3D capacitance extraction. “Extracting parasitic capacitances” as described herein refers to a design process step in which the unwanted capacitances between various circuit elements are calculated. One mode for extracting capacitances is to use a “field solver” that models the actual wire shape geometry and dielectrics with an algorithm which solves electrostatic equations for capacitance calculation-either a differential or integral form of Maxwell's equations could be used. The field solver approach is very compute-intensive and can take about one week to complete to an acceptable accuracy for a moderate sized macro of 50,000 nets, even using sophisticated parallel-processing computing hardware.

As will be appreciated by the skilled artisan, the capacitance, C, of a parallel plate capacitor is given by C=εA/d, where ε is the permittivity of the dielectric, A is the area, and d is the distance between the plates. With constant area and permittivity, increasing d (spacing) will lower the capacitance C. Increasing the spacing also reduces the chances of dielectric breakdown. While the parasitic capacitance between wires will differ somewhat from the ideal value calculated between parallel plates, the simple formula provides useful insights.

In one or more embodiments, the impact of the capacitance (e.g. parasitic capacitance) on circuit performance is assessed. In one or more embodiments, the assessment can be accomplished by conventional calculations of timing delays and/or circuit noise. In one or more embodiments, the assessment could instead be accomplished by application of machine learning to a listing of total extracted capacitances for some or all of the wires in the target layer. Then, in response to the assessment of impact on circuit performance, the design of the integrated circuit is modified to adjust the spacing between wires. For example, if the parasitic capacitance is too high, increase wire-to-wire spacing; if parasitic capacitance is not too high, spacing can be decreased. Optionally, fabricate an integrated circuit according to the modified design.

For those skilled in the art, there is an understanding that the technology node one uses to build a chip will place some constraints on acceptable wire widths and spacings on any given metal layer. These considerations provide some natural bounds for the number of patterns by specifying min/max widths and spacings for wires. Additionally, there are some physical limits that one might use to set the upper/lower bounds of these values. For example, one might say that if the spacing between wires goes above a certain threshold, treat the distance between wires as infinite. Once upper and lower bounds for these sizes are set, one could then determine how many intermediate sizes one would like to consider in a pattern set. For example, if wire widths are limited to being between 100 nm and 200 nm, one could decide to generate patterns at even intervals of 10 nm between the min and max settings, resulting in eleven allowable wire widths. Of course, the sampling does not need to be uniform, as one might choose to use, for example, samples of 100 nm, 120 nm, 160 nm, 200 nm if that fits the most common wire usage in a design paradigm. One pertinent aspect is that it is possible to develop reasonable constraints on the rules used to generate this reduced pattern database to prevent its size from becoming intractable for real computation. Also, it should be noted that the potential number of wire width/spacing combinations existing in any reduced pattern database pales in comparison to the number of distinct wire patterns possible in a design, where each wire to be analyzed might contain hundreds of crossing wires with varying widths and spacings.

It is observed that the BEOL (back end of the line) wiring of current chip technologies alternates dominant direction through the sequence of metal layers, and as a consequence, it is safe to assume that the wiring immediately above and below the target wire will be predominantly in a direction orthogonal to that of the target, and that the wiring two layers above and below the target will be predominantly in a direction parallel to that of the target.

Certain principles can be inferred from the results of a field solver operating on a sufficiently large number of sample wiring patterns. One particularly useful principle is that for a target shape (a shape for which capacitances are to be calculated), the topology of the lateral shapes (where lateral shapes refer to parallel wires on the same plane as the target wire) to that target is relatively constant for the length of the target; that is, relatively few distinct lateral shapes will exist. Another principle is that, without significant loss of accuracy, the capacitance analysis can be subdivided based on regions of uniform lateral wiring, solving each independently, and combining results to get a total capacitance.

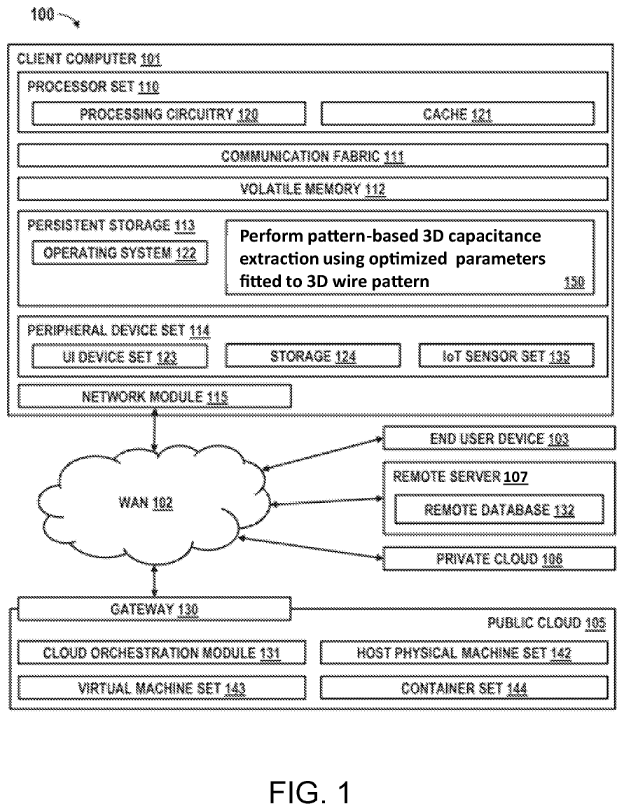

Referring to FIG. 1, computing environment 100 capable of performing pattern-based 3D capacitance extraction using optimized parameters fitted to 3D wire pattern is illustrated according to a non-limiting embodiment of the present invention. The computing environment 100 contains an example of an environment for the execution of at least some of the computer code involved in performing a pattern-based 3D capacitance extraction using optimized parameters fitted to 3D wire pattern (block 150). In addition to block 150, computing environment 100 includes, for example, computer 101, wide area network (WAN) 102, end user device (EUD) 103, remote server 107, public Cloud 105, and private Cloud 106. In this embodiment, computer 101 includes processor set 110 (including processing circuitry 120 and cache 121), communication fabric 111, volatile memory 112, persistent storage 113 (including operating system 122 and block 150, as identified above), peripheral device set 114 (including user interface (UI), device set 123, storage 124, and Internet of Things (IoT) sensor set 135), and network module 115. Remote server 107 includes remote database 132. Public Cloud 105 includes gateway 130, Cloud orchestration module 131, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 132. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a Cloud, even though it is not shown in a Cloud in FIG. 1. On the other hand, computer 101 is not required to be in a Cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing pattern-based 3D capacitance extraction using optimized parameters fitted to 3D wire pattern may be stored in block 150 in persistent storage 113.

COMMUNICATION FABRIC 111 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface type operating systems that employ a kernel. The code included in block 150 typically includes at least some of the computer code involved in performing a pattern-based 3D capacitance extraction using optimized parameters fitted to 3D wire pattern.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 107 is any computer system that serves at least some data and/or functionality to computer 101. Remote server 107 may be controlled and used by the same entity that operates computer 101. Remote server 107 represents the machine(s) that collects and store helpful and useful data for use by other computers, such as computer 101. For example, in a hypothetical case where computer 101 is designed and programmed to provide a recommendation based on historical data, then this historical data may be provided to computer 101 from remote database 132 of remote server 107.

PUBLIC CLOUD 105 is any computer system available for use by multiple entities that provides on-demand availability of computer system resources and/or other computer capabilities, especially data storage (Cloud storage) and computing power, without direct active management by the user. Cloud computing typically leverages sharing of resources to achieve coherence and economies of scale. The direct and active management of the computing resources of public Cloud 105 is performed by the computer hardware and/or software of Cloud orchestration module 131. The computing resources provided by public Cloud 105 are typically implemented by virtual computing environments that run on various computers making up the computers of host physical machine set 142, which is the universe of physical computers in and/or available to public Cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 131 manages the transfer and storage of images, deploys new instantiations of VCEs and manages active instantiations of VCE deployments. Gateway 130 is the collection of computer software, hardware, and firmware that allows public Cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public Cloud 105, except that the computing resources are only available for use by a single enterprise. While private Cloud 106 is depicted as being in communication with WAN 102, in other embodiments a private Cloud may be disconnected from the internet entirely and only accessible through a local/private network. A hybrid Cloud is a composition of multiple Clouds of different types (for example, private, community or public Cloud types), often respectively implemented by different vendors. Each of the multiple Clouds remains a separate and discrete entity, but the larger hybrid Cloud architecture is bound together by standardized or proprietary technology that enables orchestration, management, and/or data/application portability between the multiple constituent Clouds. In this embodiment, public Cloud 105 and private Cloud 106 are both part of a larger hybrid Cloud.

One or more embodiments described herein can utilize machine learning techniques to perform prediction and or classification tasks, for example. In one or more embodiments, machine learning functionality can be implemented using an artificial neural network (ANN) having the capability to be trained to perform a function. In machine learning and cognitive science, ANNs are a family of statistical learning models inspired by the biological neural networks of animals, and in particular the brain. ANNs can be used to estimate or approximate systems and functions that depend on a large number of inputs. Convolutional neural networks (CNN) are a class of deep, feed-forward ANNs that are particularly useful at tasks such as, but not limited to analyzing visual imagery and natural language processing (NLP). Recurrent neural networks (RNN) are another class of deep, feed-forward ANNs and are particularly useful at tasks such as, but not limited to, unsegmented connected handwriting recognition and speech recognition. Other types of neural networks are also known and can be used in accordance with one or more embodiments described herein.

ANNs can be embodied as so-called “neuromorphic” systems of interconnected processor elements that act as simulated “neurons” and exchange “messages” between each other in the form of electronic signals. Similar to the so-called “plasticity” of synaptic neurotransmitter connections that carry messages between biological neurons, the connections in ANNs that carry electronic messages between simulated neurons are provided with numeric weights that correspond to the strength or weakness of a given connection. The weights can be adjusted and tuned based on experience, making ANNs adaptive to inputs and capable of learning. For example, an ANN for handwriting recognition is defined by a set of input neurons that can be activated by the pixels of an input image. After being weighted and transformed by a function determined by the network's designer, the activation of these input neurons are then passed to other downstream neurons, which are often referred to as “hidden” neurons. This process is repeated until an output neuron is activated. The activated output neuron determines which character was input.

A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

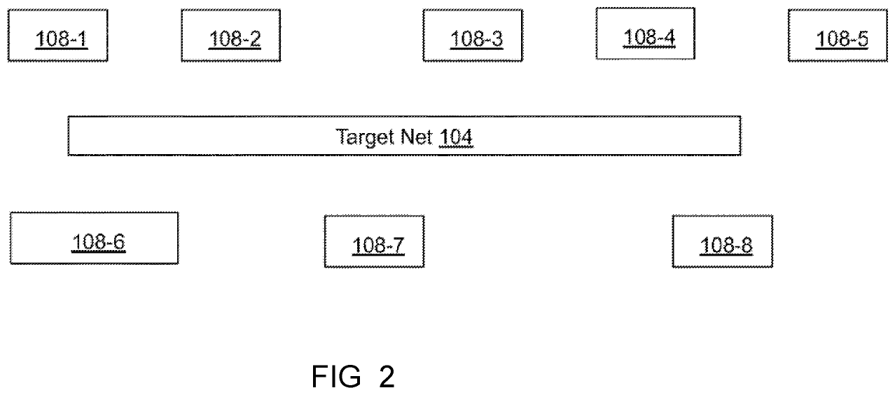

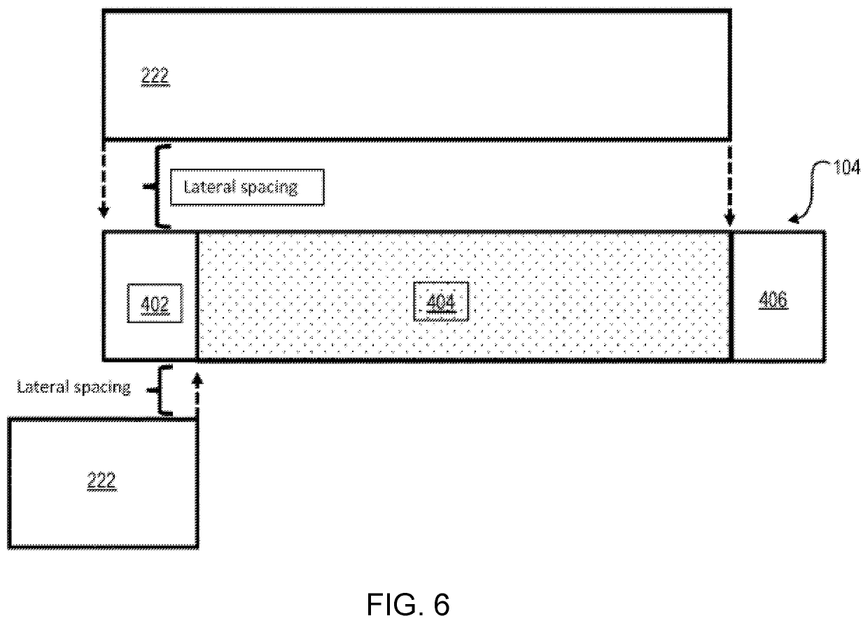

FIG. 2 illustrates a side view of a portion of a target net 104 of a VLSI design, in accordance with an example embodiment. The illustrated portion corresponds to a section of the target net 104 having a common configuration of lateral neighbor nets (not pictured), as described more fully below in conjunction with FIG. 6. For example, the illustrated portion has either a neighbor net on both sides of the same layer, a neighbor net on only one side of the same layer, or a neighbor net on neither side of the same layer (also referred to as lateral neighbors herein). Elements 108-1 through 108-8 are discussed below.

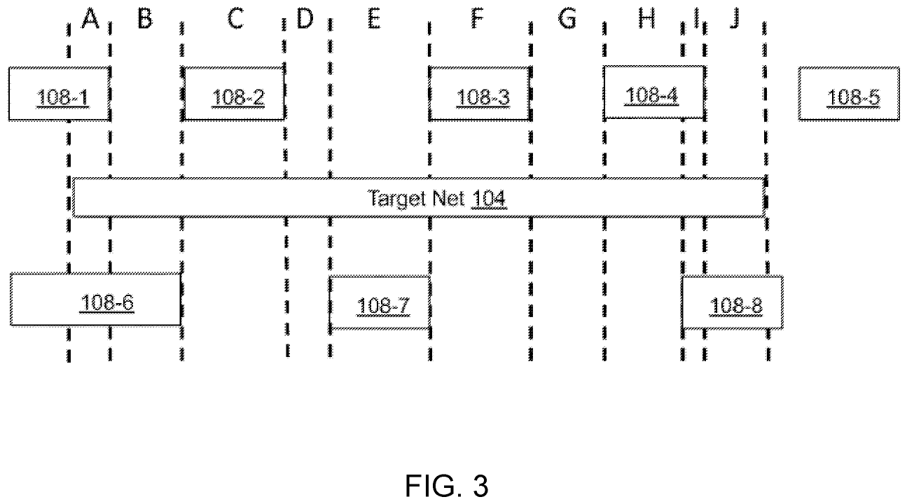

As illustrated in FIG. 3, the target net 104 (net, wire, and metal are used interchangeably herein) has orthogonal neighbor nets 108-1, 108-2, 108-3, 108-4, 108-5, 108-6, 108-7, 108-8 (collectively referred to as neighbor nets 108 herein) on the layers that are immediately above the target net 104 and immediately below the target net 104. The relationship between the target net 104 and its vertical neighbor nets 108 can be characterized by four types of relationships: 1) metal on the layer directly above and on the layer directly below the target net 104; 2) metal on the layer directly above but not on the layer below; 3) metal on the layer directly below but not on the layer above; and 4) no metal on the layer above or on the layer below. The length of the target net 104 can then be divided into segments, where each segment is characterized by one of the four relationships.

FIG. 3 illustrates the segmentation for the portion of the target net 104 of FIG. 2 based on the four defined relationships, in accordance with an example embodiment. As illustrated in FIG. 3, the length of target net 104 has been divided into ten segments (A, B, C, D, E, F, G, H, I, and J). For example, segments A and I are characterized by relationship 1; segments C, F, and H are characterized by relationship 2; segments B, E, and J are characterized by relationship 3; and segments D and G are characterized by relationship 4. These individual metal relationships can be represented with data saved from analyses of simple 2D configurations. Such configurations can include neighboring shapes on the same layer as the target net 104. This segmentation process is used to decompose the disclosed capacitance analysis into several 2D analyses. However, it is important to note that, as described more fully below, this basic form of segmentation based on actual spacings results in some loss of accuracy due to insufficient modeling of fringing capacitance. Thus, an effective space function method is introduced that alters this segmentation process to more accurately account for fringing capacitance.

### Example of a Typical 2D Simulation Input

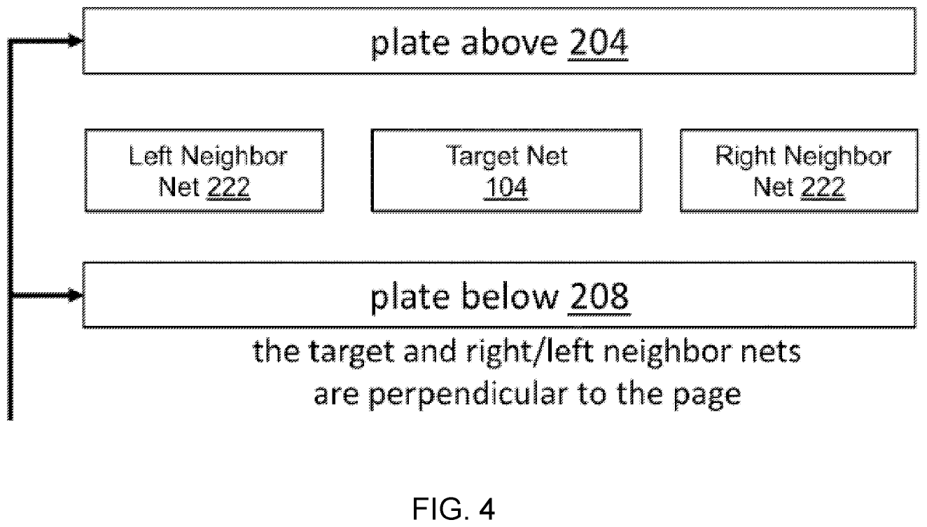

FIG. 4 illustrates a target net 104 having metal directly above (plate 204), metal directly below (plate 208), and left and right neighbor nets 222 to either side on the same layer, in accordance with an example embodiment. In the example of FIG. 4, the plates 204, 208 in the 2D simulation can be thought to represent the crossing neighbor nets 108 that are above and below the target net 104. Neighbor nets that reside two layers above and/or two layers below the target net 104 may also be considered. The configuration of FIG. 4 is analyzed with a highly accurate simulator, such as a field solver, with, for example, a finite difference analysis typically using reflective boundary conditions, a boundary-element analysis, or a random walk analysis. Suitable boundary conditions include reflective boundary conditions where reflecting plates are introduced surrounding the 2D region to be solved; the use of grounded plates surrounding the 2D region; extension of the region to infinity in all directions, and the like. For finite difference and finite element methods, reflective or grounded boundaries are used. For boundary element methods, extension to infinity is often preferred. In one example embodiment, finite difference with reflective boundary conditions is used. Given the teachings herein, the skilled artisan will be able to select appropriate boundary conditions.

In one example embodiment, these cases are pre-analyzed and then retrieved using a capacitance table lookup technique. The following setups can be created to represent possible local relationships, and solved in a field solver, including: a neighbor net 222 to the left of the target net 104, a neighbor net 222 to the right of the target net 104, a neighbor net 204 above the target net 104, and a neighbor net 208 below the target net 104; a neighbor net 222 to the left of the target net 104, a neighbor net 222 to the right of the target net 104, and a neighbor net 204 above the target net 104; a neighbor net 222 to the left of the target net 104, a neighbor net 222 to the right of the target net 104, and a neighbor net 208 below the target net 104; a neighbor net 222 to the left of the target net 104 and a neighbor net 222 to the right of the target net 104; and all of the above combinations without a left neighbor net 222, all of the above combinations without a right neighbor net 222, and all of the above combinations with no left neighbor net 222 and no right neighbor net 222.

For practical reasons, a maximum lateral distance to a neighbor net 222 is defined based on the wiring layer and the technology, and a neighbor net 222 is considered at that distance even if there is no actual wire that is closer. Thus, the choices listed above reduce to a neighbor net 222 on both sides (with possibly different spacings to each side) together with different combinations of neighbor nets above 2004 and below 206 the target net 104. For simplification of the analysis, a plate two layers above will also be assumed if there is no neighbor net 204 directly above the target net 104 and a plate two layers below will be assumed if there is no neighbor net 208 directly below the target net 104.

Thus, in one example embodiment, the following combinations are considered for the scenario with two lateral neighbor nets 222 (with possibly different spacings to each side):
1) metal 204 directly above the target net 104 and a plate two layers below the target net 104;
2) a plate two layers above the target net 104 and metal 208 directly below the target net 104;
3) metal 204 directly above the target net 104 and metal 208 directly below the target net 104; and
4) a plate two layers above the target net 104 and a plate two layers below the target net 104.

Simple target capacitances for the above capacitance Cup, the below capacitance Cdown, the left-side capacitance Cleft, and the right-side capacitance Cright can be calculated from the field solver analyses for each configuration and stored as per-unit-length values for the target net 104.

### Effective Space Function Method

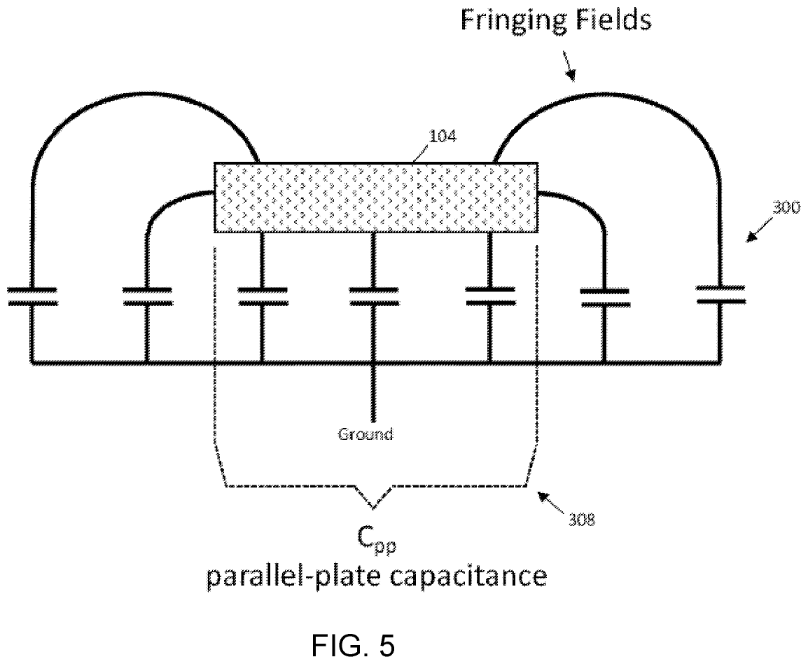

FIG. 5 illustrates the fringe capacitance 300, and parallel-plate capacitance CPP, 308 for a target net, in accordance with an example embodiment. It should be noted that, if segmentation (FIG. 3) were performed and capacitance values were calculated based on the actual spacings between crossing wires, inaccuracies would be introduced by these 2D analyses, since the problem is inherently a 3D problem and effects such as fringe capacitance 300 at crossing wire edges would not be taken into account. To overcome this inaccuracy, a modification to the metal shapes and the spacing between them is implemented using an effective space function. A properly chosen effective space function that is formed as a function of the actual space and that offers control of more than one function parameter, can assist in calculating all four capacitance components (Cup, Cdown, Cleft, and Cright) by scaling the 2D capacitance values based on spacing observations. These resulting four capacitance components will closely match field-solver results for wiring cases obeying the orthogonal wiring assumptions.

FIG. 6 illustrates a top-view of a target net 104 having two neighbor nets 222 on the same layer, in accordance with an example embodiment. In one example embodiment, the target net 104 is split into sections based on the existence or absence of a left neighbor net 222 and the existence or absence of a right neighbor net 222. Each section (referred to as an area herein) is then analyzed individually, as described more fully below. For example, target areas 402, 404, 406 of the target net 104 are analyzed individually.

### Effective Space Definition

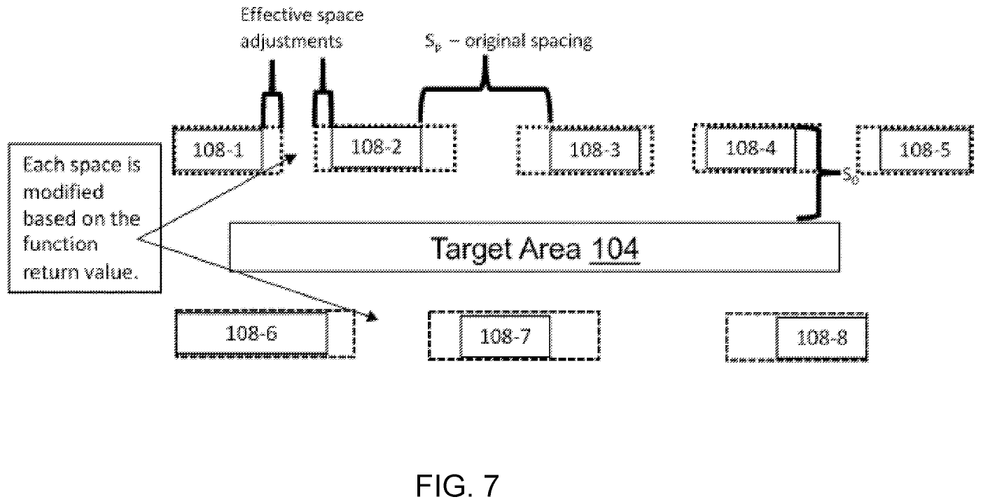

FIG. 7 illustrates a side-view of target area 404 with cross-sectional views of the neighbor nets 108 on the layer above and the layer below the target net 104, in accordance with an example embodiment. Recall that the 2D capacitances are defined per-unit-length of a wire. In one example embodiment, an effective spacing is defined that is used in place of the actual spacing when apportioning the various 2D results. Thus, once a target area 402, 404, 406 is selected, such as the target area 404, the original physical spacing (Sp) is adjusted based on the effective space adjustments. As illustrated in FIG. 7, solid rectangles represent the physical width of the neighbor nets 108 and dashed rectangles represent the effective width of the neighbor nets 108.

In one or more embodiments, the effective space function depends solely on the actual space of the crossing wires while allows for additional control of two or more functional parameters. Each space between neighbor nets 108 can be reduced and the metal widths increased, as a function of the original space and a modification of two or more function parameters, to define segments of the target area 404. These segments can then be used when apportioning the capacitance values from the necessary pre-characterized 2D results, in order to account for fringing and other real-configuration effects.

The effective space function is defined as a parameterized function of the original space and two or more function parameters that can be adjusted. The parameters can be set to account for 3D effects and match closely to field solver results, while also ensuring a best or optimized 3D wiring pattern is determined to perform a capacitance extraction. According to a non-limiting embodiment, the effective space function is defined as:

$$f ( s ) = {s}^{2} ( s + {S}_{0} ) / ( {s}^{2} + 2 s {S}_{0} + {S}_{0} {S}_{1} ) ,$$

“s” is a given spacing between neighbor net; and
S₀ and S₁ are adjustable parameters that are set to obtain best matching wiring patterns determined using a fitting process.

According to at least one non-limiting embodiment, S₀ and S₁ are chosen independently for the above and below crossing wires, so, for this suggested implementation, there are four parameters to fit. Parameter S₀ can be defined as a first sum of the vertical distance from the target net 104 to the bottom of the above layer plus the thickness of the above layer, i.e., (S₀=(height to above/below metal)+(thickness of above/below metal)), where the value is adjusted or set to adjusted to work best for a wider space between crossing wires. S₁ can be defined as a second sum of the vertical distance from the target net 104 to the bottom of the above layer plus the thickness of the above layer, i.e., (S₁=(height to above/below metal)+(thickness of above/below metal)), where the value is adjusted or set to adjusted to work best for a narrower space between crossing wires. It should be appreciated that higher refinement can be obtained with increased polynomial orders, or with other forms of equations that define the effective space function without departing from the scope of the present disclosure.

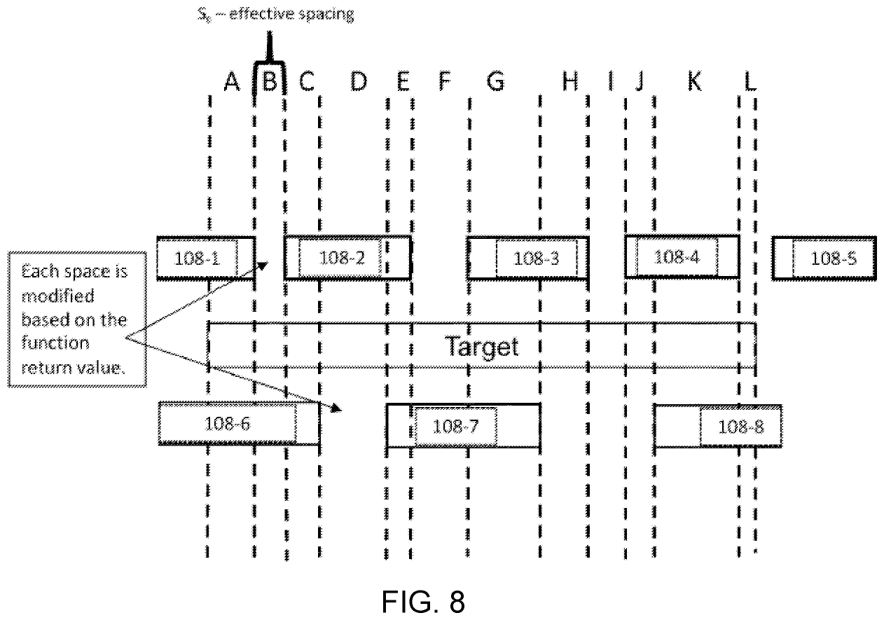

FIG. 8 illustrates the configuration of FIG. 7 where each original spacing has been modified to derive the effective spacing (sₑ) based on an effective spacing function return value, in accordance with an example embodiment. The method for determining the effective spacing and effective net widths is described below by way of example in conjunction with FIG. 7. As illustrated in FIG. 8, the dashed rectangles represent the physical width and the solid rectangles represent the effective width of the neighbor nets 108.

According to a non-limiting embodiment, a reduced pattern database can be used to obtain a 3D wiring pattern to provide fast/accurate extraction results when extracting parasitic capacitances from a circuit design. The reduced pattern database includes a number of regularly repeating wire patterns above and below the target wire. Different embodiments of the invention use different reduced pattern databases. For each pattern in a pattern set, a field solver finds the capacitance per unit length for an infinitely repeating pattern of the crossing wire pattern. Key values (related to the crossing wires) that will define each distinct pattern include the cumulative crossing wire widths (above and below the target) and the discrete crossing wire spacings (both above and below the target). Allowing for infinite granularity in wire spacings and widths would of course lead to an infinite pattern set. However, it is possible to intelligently constrain the granularity of these values and still produce a working system.

The aforementioned considerations provide some natural bounds for the number of patterns by specifying min/max widths and spacings for wires. Additionally, there are some physical limits that one might use to set the upper/lower bounds of these values. For example, one might say that if the spacing between wires goes above a certain threshold, treat the distance between wires as infinite. Once upper and lower bounds for these sizes are set, one could then determine how many intermediate sizes one would like to consider in a pattern set. For example, if wire widths are limited to being between 100 nm and 200 nm, one could decide to generate patterns at even intervals of 10 nm between the min and max settings, resulting in eleven allowable wire widths. Of course, the sampling does not need to be uniform, as one might choose to use, for example, samples of 100 nm, 120 nm, 160 nm, 200 nm if that fits the most common wire usage in a design paradigm. One pertinent aspect is that it is possible to develop reasonable constraints on the rules used to generate this reduced pattern database to prevent its size from becoming intractable for real computation. Also, it should be noted that the potential number of wire width/spacing combinations existing in any reduced pattern database pales in comparison to the number of distinct wire patterns possible in a design, where each wire to be analyzed might contain hundreds of crossing wires with varying widths and spacings.

Considering the aforementioned principles, the number of patterns sufficient for accurate extraction is greatly reduced since the patterns can be reduced to uniform width, evenly spaced crossing wire patterns-every possible wide width and spacing combination does not have to be recognized and processed by a field solver and stored. Indeed, in one or more embodiments, each wiring pattern of the reduced pattern database has a first uniform wire width and a first uniform wire spacing in segments of a first adjacent wiring layer and has a second uniform wire width and a second uniform wire spacing in segments of a second adjacent wiring layer (opposite the first adjacent wiring layer across a target wiring layer), and the first and second uniform wire width and wire spacings are the same or different among each of the wiring patterns. In extracting the capacitance of an arbitrary wiring layout, field solutions for suitable patterns can be retrieved from the reduced pattern database, interpolated, and combined to arrive at acceptably accurate estimates of parasitic capacitance. Accordingly, for a typical wiring layer, only several thousand such patterns would be needed in contrast to probably several million suggested in the literature to achieve similar accuracy, which would likely be intractable for a typical capacitance extraction implementation.

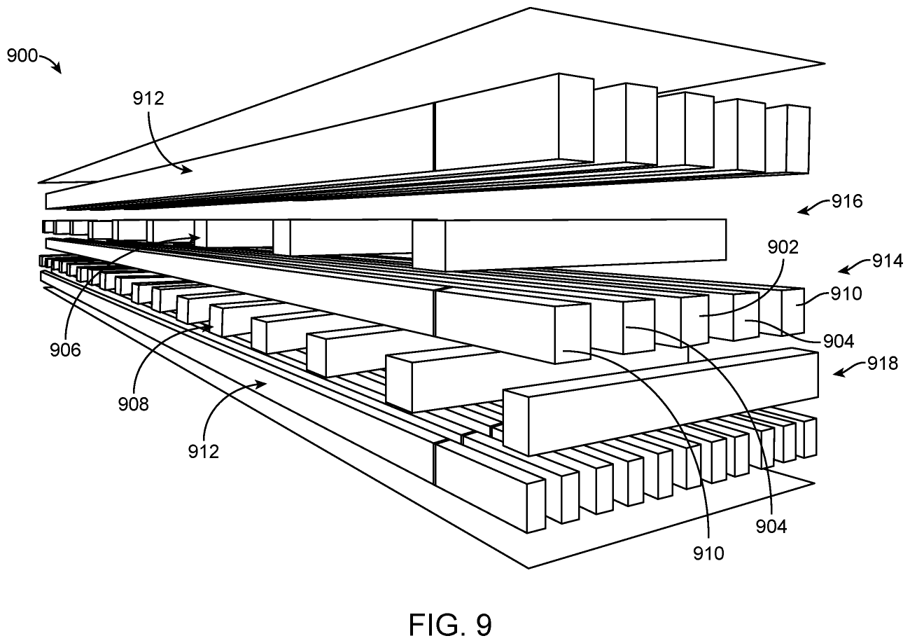

FIG. 9 illustrates an arrangement of BEOL wiring 900 defining a 3D wiring pattern according to a non-limiting embodiment. The BEOL wiring 900 includes a target wire 902, lateral neighbors 904, crossing wires 906 immediately above the target wire 902, crossing wires 908 immediately below the target wire 902, and distal wires 910, 912. The target wire 902, its lateral neighbors 904, and the distal wires 910 define a target wiring layer 914. The crossing wires 906 define a first adjacent wiring layer 916. The crossing wires 908 define a second adjacent wiring layer 918. The example of the BEOL wiring 900 illustrated in FIG. 9 presumes uniform widths and spacing between the crossing wires 906 and between the crossing wires 908. This is a useful presumption for assembling a reduced pattern database, for reasons further discussed below

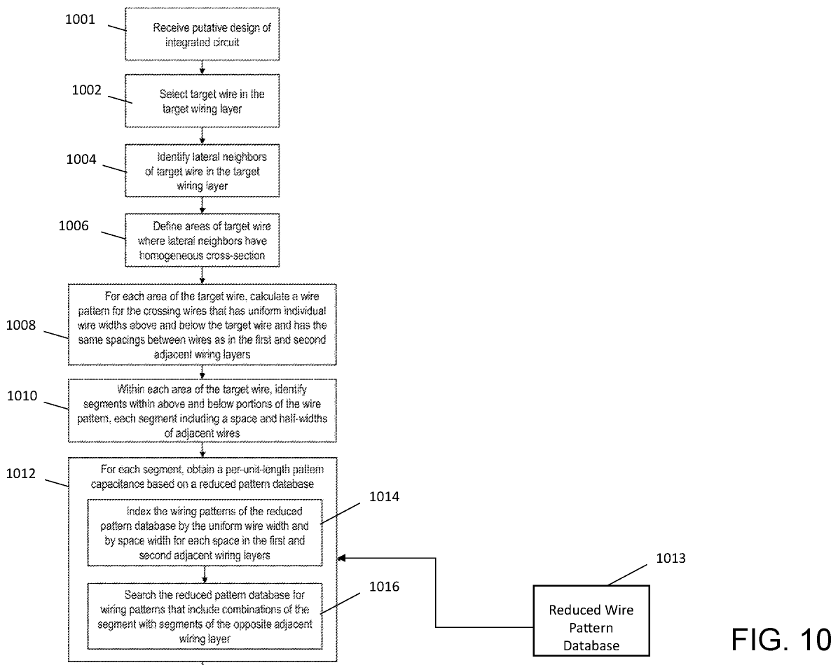

Turning to FIG. 10, a method of determining a 3D wiring pattern that can be used to perform a pattern-based 3D capacitance extraction is illustrated according to a non-limiting embodiment. At 1001 the method includes receiving a putative design of an integrated circuit. An exemplary circuit design, as shown in FIG. 9, includes the target wire 902, lateral neighbors 904, crossing wires 906 immediately above the target wire 902, crossing wires 908 immediately below the target wire 902, and distal wires 910, 912. The target wire 902, its lateral neighbors 904, and the distal wires 910 define the target wiring layer 914. The crossing wires 906 define the first adjacent wiring layer 916 above the target wiring layer 914. The crossing wires 908 define the second adjacent wiring layer 918 below the target wiring layer 914.

At 1002 select the target wire 902 disposed in the target wiring layer 914 to perform capacitance extraction. At 1004 identify lateral neighbors 904 of the target wire 902 in the target wiring layer 914. At 1006 define regions of the target wire 902 for which the lateral neighbors are homogeneous in cross-section. At 1008 for each region of the target wire, calculate a wire pattern for the crossing wires that has uniform individual wire widths above and below the target wire (widths above may be the same as or different than widths below) and has the same spacings between wires as in the first and second adjacent wiring layers 916, 918. At 1010, within each region of the target wire, identify segments within above and below portions of the wire pattern. The segments can include, for example, segments (A, B, C, D, E, F, G, H, I, and J) shown in FIG. 3. Reflect the wires and spaces in each adjacent wiring layer at the ends of each region. At 1012, obtain a per-unit-length capacitance (Cij) for each above/below segment combination, identified by a choice of i and a choice of (j), based on a reduced pattern database 1013. The indices (i) and (j) index the space above and space below. Interpolate when necessary to approximate a corresponding pattern, e.g. when there are patterns for 120 nm wire width and two 50 nm spaces or for 130 nm wire width and two 40 nm spaces, and the actual spacing is one 40 nm space and one 50 nm space with 120 nm wire width, combine the two existing patterns to approximate the target capacitance. This supports arbitrary widths and spaces by the interpolation process, which allows the model to work in the presence of width bias. “Width bias” is variations from grid-like widths as a result of semiconductor manufacturing. Accordingly, to account for width bias, a continuous variation in width values is supported, not just a few incremental widths.

Step 1012 of obtaining per-unit-length capacitances includes steps 1014 and 1016. At 1014, index the wiring patterns of the reduced pattern database by the wires in the wiring patterns determined in 1008 in the first and second adjacent (above and below) wiring layers. At 1016, search the reduced pattern database for wiring patterns that include combinations of the segment with segments of the opposite adjacent wiring layer. In other words, at 1014 enumerate the above and below segments by indexes (i) and (j) respectively. At 1016, for each combination of ith segment above and jth segment below, search the reduced pattern database for wiring patterns that include the above width and space, and the below width and space, associated with those two segments. Such an access will also include the lateral environment for the region, i.e., the target width and the two lateral neighbor spacings and widths. Each such result will include a set of per-unit-length capacitances.

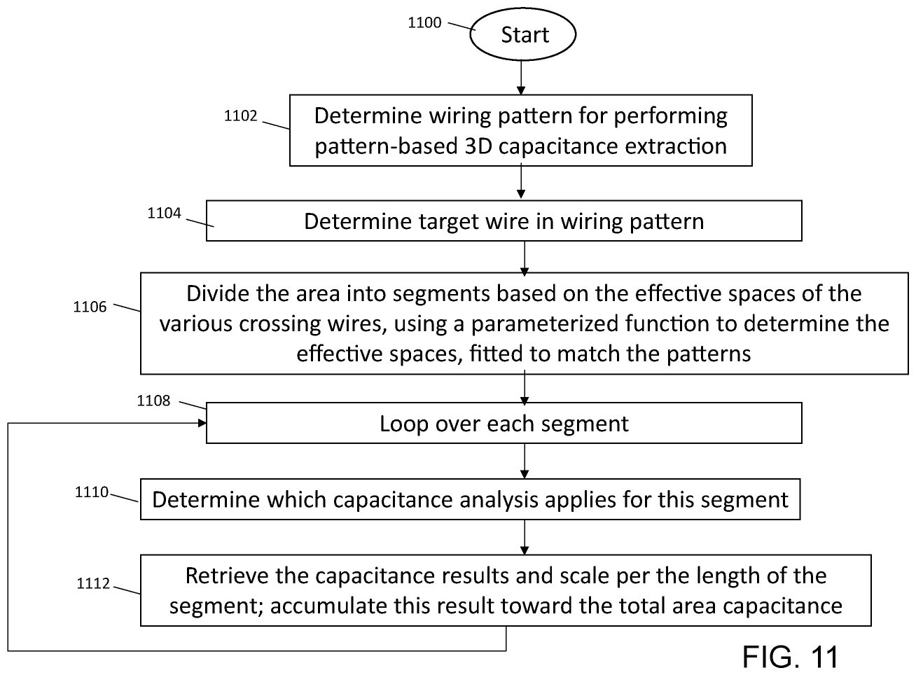

After determining a wiring pattern to be used for performing a pattern-based 3D capacitance extraction operation, one or more areas of a target wire included the wiring pattern can be analyzed using the optimal fitted parameterized function (f(s)=s²(s+S₀)/(s²+2sS₀+S₀S₁)) described herein. FIG. 11, for example, is a flow diagram illustrating a method for analyzing an area of a target wire using the optimal fitted parameterized function (f(s)=s²(s+S₀)/(s²+2sS₀+S₀S₁)). The method begins at operation 1100, and determines a wiring pattern f at operation 1102. According to a non-limiting embodiment, various wiring patterns with uniform spacing of crossing wires are chosen and pre-characterized using a three-dimensional (3D). In at least one embodiment, the wiring pattern can be determined, for example, using the method corresponding to FIG. 10. Operations of analyzing target shapes, segmenting, determining effective spaces can be performed as described herein. At operation 1104, a target wire included in the wiring pattern is determined, and a target area of the target wire is divided into segments at operation 1106. According to a non-limiting embodiment, the segments can be determined based on the effective spaces of the various crossing wires, using the parameterized function (f(s)=s²(s+S₀)/(s²+2sS₀+S₀S₁)) to determine the effective spaces, fitted to match the pattern. At operation 1108, each segment is looped over, and a type of capacitance analysis to apply to the segments is determined at operation 1110. At operation 1112, the capacitance results are retrieved and scaled per the length of the segment. The results are accumulated to obtain a total capacitance of the target area.

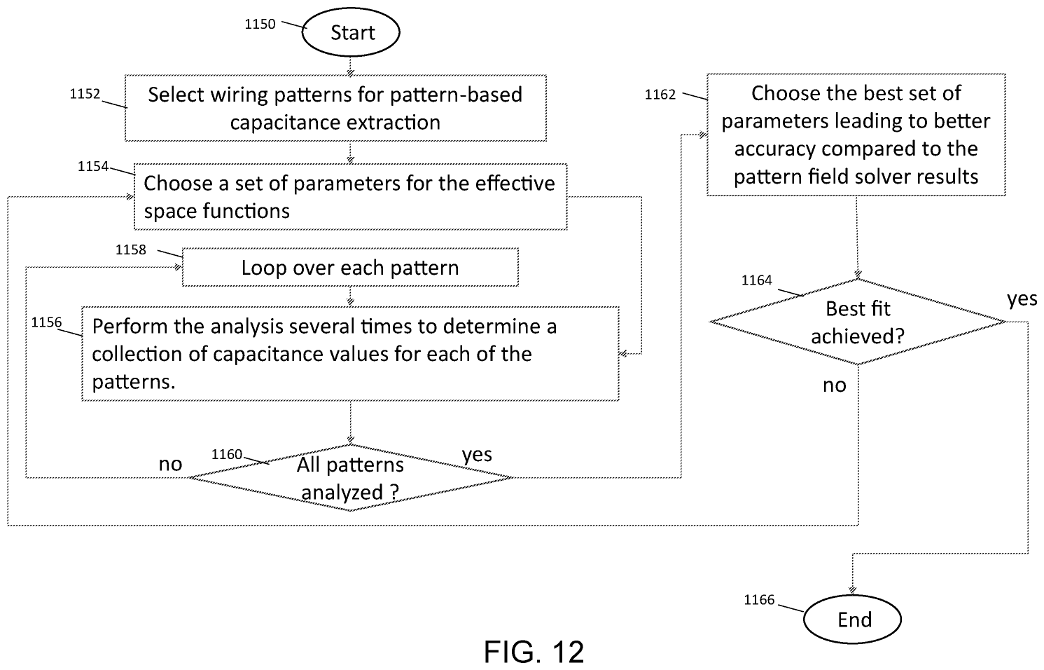

As described herein, a parameter fitting process is provided for choosing function parameters that closely match that of available wiring patterns that can be selected to perform pattern-based 3D capacitance extraction. FIG. 12, illustrates a method for performing an iterative parameter fitting process according to a non-limiting embodiment of the present disclosure. The method begins at operation 1150 and one or more wiring patterns are selected at operation 1152. According to a non-limiting embodiment, various wiring patterns with uniform spacing of crossing wires are chosen and pre-characterized using a three-dimensional (3D) analysis. Operations of analyzing target shapes, segmenting, determining effective spaces can be performed as described herein. At operation 1154, a set of parameters are chosen for the optimal fitted parameterized effective space function (f(s)=s²(s+S₀)/(s²+2sS₀+S₀S₁)) corresponding to a selected wiring pattern. At operation 1156, the target area of a target wire is analyzed using the optimal fitted parameterized function. According to a non-limiting embodiment, the collection of capacitance values for each wiring pattern can be determined, for example, using the method corresponding to FIG. 11. At operation 1158, each selected wiring pattern is looped over and analyzed using the optimal fitted parameterized function to determine a collection of capacitance values for each wiring pattern. At operation 1160, a determination is made as to whether all wiring patterns have been analyzed, i.e., the capacitance values for all selected wiring patterns have been obtained. If not, the method returns to operation 1158 and continues looping over the selected wiring patterns.

When, however, all wiring patterns have been analyzed, the best set of parameters leading to the best accuracy compared to a pattern field solver results are selected at operation 1162. At operation 1164, a determination is made as to whether a best fit is achieved. According to a non-limiting embodiment, the best fit can be achieved by determining whether the average difference for all samples drops below a threshold. In another example, the best fit can be achieved by comparing the maximum difference outlier to a certain percent of the correct answer, and determining the best fit is achieved when the maximum difference outlier falls within the certain percent of the correct answer. When the best fit has not yet been achieved, the method returns to operation 1154 and selects new parameters for the optimal fitted parameterized effective space function (f(s)=s²(s+S₀)/(s²+2sS₀+S₀S₁)). When, however, the best fit is achieved, the method ends at operation 1166.

One or more embodiments can be at least partially implemented in the context of a cloud or virtual machine environment, although this is exemplary and non-limiting.

It should be noted that any of the methods described herein can include an additional step of providing a system comprising distinct software modules embodied on a computer readable storage medium; the modules can include, for example, any or all of the appropriate elements depicted in the block diagrams and/or described herein; by way of example and not limitation, any one, some or all of the modules/blocks and or sub-modules/sub-blocks described. The method steps can then be carried out using the distinct software modules and/or sub-modules of the system, as described above, executing on one or more hardware processors. Further, a computer program product can include a computer-readable storage medium with code adapted to be implemented to carry out one or more method steps described herein, including the provision of the system with the distinct software modules.

One example of user interface that could be employed in some cases is hypertext markup language (HTML) code served out by a server or the like, to a browser of a computing device of a user. The HTML is parsed by the browser on the user's computing device to create a graphical user interface (GUI).

Exemplary Design Process Used in Semiconductor Design, Manufacture, and/or Test. In addition, one or more embodiments integrate the parasitic capacitance extraction techniques herein with semiconductor integrated circuit design simulation, test, layout, and/or manufacture.

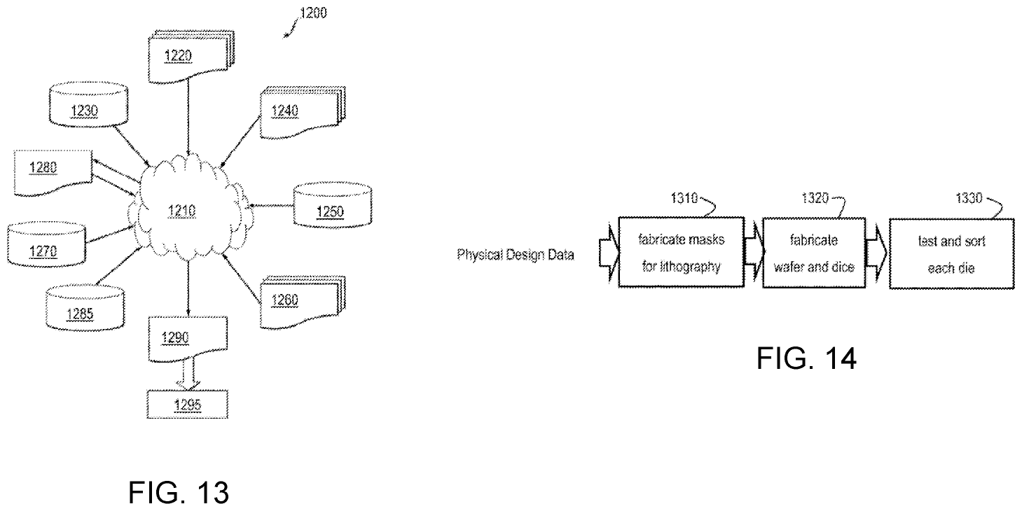

FIG. 13 shows a block diagram of an exemplary design flow 1200 used for example, in semiconductor IC logic design, simulation, test, layout, and manufacture. Design flow 1200 includes processes, machines and/or mechanisms for processing design structures or devices to generate logically or otherwise functionally equivalent representations of design structures and/or devices, such as those that can be analyzed using parasitic capacitance extraction or the like. The design structures processed and/or generated by design flow 1200 may be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 1200 may vary depending on the type of representation being designed. For example, a design flow 1200 for building an application specific IC (ASIC) may differ from a design flow 1200 for designing a standard component or from a design flow 1200 for instantiating the design into a programmable array, for example a programmable gate array (PGA) or a field programmable gate array (FPGA) offered by Altera® Inc. or Xilinx® Inc.

FIG. 13 illustrates multiple such design structures including an input design structure 1220 that is preferably processed by a design process 1210. Design structure 1220 may be a logical simulation design structure generated and processed by design process 1210 to produce a logically equivalent functional representation of a hardware device. Design structure 1220 may also or alternatively comprise data and/or program instructions that when processed by design process 1210, generate a functional representation of the physical structure of a hardware device. Whether representing functional and/or structural design features, design structure 1220 may be generated using electronic computer-aided design (ECAD) such as implemented by a core developer/designer. When encoded on a gate array or storage medium or the like, design structure 1220 may be accessed and processed by one or more hardware and/or software modules within design process 1210 to simulate or otherwise functionally represent an electronic component, circuit, electronic or logic module, apparatus, device, or system. As such, design structure 1220 may comprise files or other data structures including human and/or machine-readable source code, compiled structures, and computer executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 1210 preferably employs and incorporates hardware and/or software modules for synthesizing, translating, or otherwise processing a design/simulation functional equivalent of components, circuits, devices, or logic structures to generate a Netlist 1280 which may contain design structures such as design structure 1220. Netlist 1280 may comprise, for example, compiled or otherwise processed data structures representing a list of wires, discrete components, logic gates, control circuits, I/O devices, models, etc. that describes the connections to other elements and circuits in an integrated circuit design. Netlist 1280 may be synthesized using an iterative process in which netlist 1280 is resynthesized one or more times depending on design specifications and parameters for the device. As with other design structure types described herein, netlist 1280 may be recorded on a machine-readable data storage medium or programmed into a programmable gate array. The medium may be a nonvolatile storage medium such as a magnetic or optical disk drive, a programmable gate array, a compact flash, or other flash memory. Additionally, or in the alternative, the medium may be a system or cache memory, buffer space, or other suitable memory.

Design process 1210 may include hardware and software modules for processing a variety of input data structure types including Netlist 1280. Such data structure types may reside, for example, within library elements 1230 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 1240, characterization data 1250, verification data 1260, design rules 1270, and test data files 1285 which may include input test patterns, output test results, and other testing information. Design process 1210 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 1210 without deviating from the scope and spirit of the invention. Design process 1210 may also include modules for performing standard circuit design processes such as parasitic capacitance extraction, verification, design rule checking, place and route operations, etc. Improved parasitic capacitance extraction can be performed as described herein.

Design process 1210 employs and incorporates logic and physical design tools such as HDL compilers and simulation model build tools to process design structure 1220 together with some or all of the depicted supporting data structures along with any additional mechanical design or data (if applicable), to generate a second design structure 1290. Design structure 1290 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 1220, design structure 1290 preferably comprises one or more files, data structures, or other computer-encoded data or instructions that reside on data storage media and that when processed by an ECAD system generate a logically or otherwise functionally equivalent form of one or more IC designs or the like. In one embodiment, design structure 1290 may comprise a compiled, executable HDL simulation model that functionally simulates the devices to be analyzed.

Design structure 1290 may also employ a data format used for the exchange of layout data of integrated circuits and/or symbolic data format (e.g. information stored in a GDSII (GDS2), GL1, OASIS, map files, or any other suitable format for storing such design data structures). Design structure 1290 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., lib files). Design structure 1290 may then proceed to a stage 1295 where, for example, design structure 1290: proceeds to tape-out, is released to manufacturing, is released to a mask house, is sent to another design house, is sent back to the customer, etc.

Once the physical design data is obtained, based, in part, on the design processes described herein, an integrated circuit designed in accordance therewith can be fabricated according to known processes that are generally described with reference to FIG. 14. Generally, a wafer with multiple copies of the final design is fabricated and cut (i.e., diced) such that each die is one copy of the integrated circuit. At block 1310, the processes include fabricating masks for lithography based on the finalized physical layout. At block 1320, fabricating the wafer includes using the masks to perform photolithography and etching. Once the wafer is diced, testing and sorting each die is performed at 1330 to filter out any faulty die.

Various embodiments are described herein with reference to the related drawings. Alternative embodiments can be devised without departing from the scope of the present disclosure. Various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. Moreover, the various tasks and process steps described herein can be incorporated into a more comprehensive procedure or process having additional steps or functionality not described in detail herein.

One or more of the methods described herein can be implemented with any or a combination of the following technologies, which are each well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

For the sake of brevity, conventional techniques related to making and using aspects of the present disclosure may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description, but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The present disclosure may be a system, a method, and/or a computer program product at any possible technical detail level of integration. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instruction by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the present disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method for analyzing an area of a target wire, the method comprising:
determining a wiring pattern for performing pattern-based 3D capacitance extraction;
determining the target wire included in the wiring pattern;
dividing the target wire into segments based on effective spaces of various crossing wires;
determining a capacitance analysis that applies for each of the segments;
determining a plurality of capacitance results corresponding to the capacitance analysis applied to each of the segments; and
accumulating the plurality of capacitance results to extract a total capacitance corresponding to the target wire,
wherein the segments are based on an effective spacing of crossing wires included in the wiring pattern, which are located above the target wire and extend across the target wire, and
wherein the effective spaces of the various crossing wires are determined using a parameterized function (f(s)) that implements at least two adjustable parameters that are set to determine the wiring pattern using a fitting process.

2. The method of claim 1, wherein the parameterized function (f(s)=s²(s+S₀)/(s²+2sS₀+S₀S₁)), which is fitted to match the wiring pattern,
where “s” is a physical spacing of a pair of adjacent neighbor wires,
“S₀” is a first adjustable parameter among the at least two adjustable parameters and is defined as a first sum of a vertical distance from the target wire to a bottom of an above crossing wire plus a thickness of an above crossing wire, where the value is adjusted for a first spacing between a pair of neighboring crossing wires, and
“S₁” is a second adjustable parameter among the at least two adjustable parameters and is defined as a second sum of a vertical distance from the target wire to a bottom of an above crossing wire plus a thickness of an above crossing wire, where the value is adjusted for a second spacing between a pair of neighboring crossing wires, the second spacing being narrower than the first spacing.

3. The method of claim 2, further comprising:
calculating the effective spacing for each physical spacing between two or more neighbor wires of a target wire of a putative design of an integrated circuit;
determining segment boundaries based on the calculated effective spacing to define the segments for the target wire;
selecting one of the segments;
identifying a metal configuration for the selected segment;
accessing a table of capacitance per-unit-length for the identified metal configuration to return an above capacitance value, a below capacitance value, a left-side capacitance value, and a right-side capacitance value for the corresponding segment;
scaling the above capacitance value, the below capacitance value, the left-side capacitance value, and the right-side capacitance value based on a corresponding segment length determined from the calculated effective spacing;
assessing an impact of the scaled capacitance values on circuit performance; and
in response to the assessment of impact on the circuit performance, producing a modified design by modifying the putative design of the integrated circuit.

4. The method of claim 3, further comprising repeating the selecting,
identifying, accessing and scaling operations for each remaining segment of the target wire.

5. The method of claim 4, further comprising:
summing the scaled above capacitance values for all segments of the target wire;
summing the scaled below capacitance values for all segments of the target wire;
summing the scaled left-side capacitance values for all segments of the target wire; and
summing the scaled right-side capacitance values for all segments of the target wire, wherein the assessed impact is based on the summed scaled capacitance values.

6. The method of claim 5, further comprising determining values for the above capacitance value, the below capacitance value, the left-side capacitance value, and the right-side capacitance value based on a field solver analysis of each metal configuration and storing the determined values in the table as per-unit-length values for the target wire.

7. The method of claim 6, wherein the field solver analysis is performed using a field solver tool.

8. The method of claim 7, further comprising performing the field solver analysis with at least one of a finite difference analysis using reflective boundary conditions, a boundary-element analysis, and a random walk analysis.

9. A computing system comprising:
a memory; and
at least one processor, coupled to said memory, and operative to perform operations comprising:
determine a wiring pattern for performing pattern-based 3D capacitance extraction;
determine a target wire included in the wiring pattern;
divide the target wire into segments based on effective spaces of the various crossing wires;
determine a capacitance analysis that applies for each of the segments;
determine a plurality of capacitance results corresponding to the capacitance analysis applied to each of the segments; and
accumulate the plurality of capacitance results to extract a total capacitance corresponding to the target wire,
wherein the segments are based on an effective spacing of crossing wires included in the wiring pattern, which are located above the target wire and extend across the target wire, and
wherein the effective spaces of the various crossing wires are determined using a parameterized function (f(s)) that implements at least two adjustable parameters that are set to obtain the wiring pattern using a fitting process.

10. The computing system of claim 9, wherein the parameterized function (f(s)=s2(s+S0)/(s2+2sS0+S0S1)), which is fitted to match the wiring pattern,
where “s” is a physical spacing of a pair of adjacent neighbor wires,
“S₀” is a first adjustable parameter among the at least two adjustable parameters and is defined as a first sum of a vertical distance from the target wire to a bottom of an above crossing wire plus a thickness of the above crossing wire, where the value is adjusted for a first spacing between a pair of neighboring crossing wires, and
“S₁” is a second adjustable parameter among the at least two adjustable parameters and is defined as a second sum of a vertical distance from the target wire to a bottom of an above crossing wire plus a thickness of the above crossing wire, where the value is adjusted for a second spacing between a pair of neighboring crossing wires, the second spacing being narrower than the first spacing.

11. The computing system of claim 10, further comprising:
calculating the effective spacing for each physical spacing between two or more neighbor wires of a target wire of a putative design of an integrated circuit;
determining segment boundaries based on the calculated effective spacing to define the segments for the target wire;
selecting one of the segments;
identifying a metal configuration for the selected segment;
accessing a table of capacitance per-unit-length for the identified metal configuration to return an above capacitance value, a below capacitance value, a left-side capacitance value, and a right-side capacitance value for the corresponding segment;
scaling the above capacitance value, the below capacitance value, the left-side capacitance value, and the right-side capacitance value based on a corresponding segment length determined from the calculated effective spacing;
assessing an impact of the scaled capacitance values on circuit performance; and
in response to the assessment of impact on the circuit performance, producing a modified design by modifying the putative design of the integrated circuit.

12. The computing system of claim 11, further comprising repeating the selecting, identifying, accessing and scaling operations for each remaining segment of the target wire.

13. The computing system of claim 12, further comprising:
summing the scaled above capacitance values for all segments of the target wire;
summing the scaled below capacitance values for all segments of the target wire;
summing the scaled left-side capacitance values for all segments of the target wire; and
summing the scaled right-side capacitance values for all segments of the target wire, wherein the assessed impact is based on the summed scaled capacitance values.

14. The computing system of claim 13, further comprising determining values for the above capacitance value, the below capacitance value, the left-side capacitance value, and the right-side capacitance value based on a field solver analysis of each metal configuration and storing the determined values in the table as per-unit-length values for the target wire.

15. The computing system of claim 14, wherein the field solver analysis is performed using a field solver tool.

16. The computer system of claim 15, wherein the field solver performs the field solver analysis with at least one of a finite difference analysis using reflective boundary conditions, a boundary-element analysis, and a random walk analysis.

17. A computer program product to control a computer system to perform a pattern-based 3D capacitance extraction perform a pattern-based 3D capacitance extraction, the computer program product comprising a computer readable storage medium having program instructions embodied therewith, the program instructions executable by an electronic computer processor to control the computer system to perform operations comprising:
determine a wiring pattern for performing pattern-based 3D capacitance extraction;
determine a target wire included in the wiring pattern;
divide the target wire into segments based on effective spaces of the various crossing wires;
determine a capacitance analysis that applies for each of the segments;
determine a plurality of capacitance results corresponding to the capacitance analysis applied to each of the segments; and
accumulate the plurality of capacitance results to extract a total capacitance corresponding to the target wire,
wherein the segments are based on an effective spacing of crossing wires included in the wiring pattern, which are located above the target wire and extend across the target wire, and
wherein the effective spaces of the various crossing wires are determined using a parameterized function (f(s)) that implements at least two adjustable parameters that are set to obtain the wiring pattern using a fitting process.

18. The computer program product of claim 17, wherein the effective spaces of the various crossing wires are determined using a parameterized function (f(s)=s2(s+S0)/(s2+2sS0+S0S1)), which is fitted to match the wiring pattern,
where “s” is a physical spacing of a pair of adjacent neighbor wires,
“S₀” is a first adjustable parameter among the at least two adjustable parameters and is defined as a first sum of a vertical distance from the target wire to a bottom of an above crossing wire plus a thickness of the above crossing wire, where the value is adjusted for a first spacing between a pair of neighboring crossing wires, and
“S₁” is a second adjustable parameter among the at least two adjustable parameters and is defined as a second sum of a vertical distance from the target wire to a bottom of an above crossing wire plus a thickness of the above crossing wire, where the value is adjusted for a second spacing between a pair of neighboring crossing wires, the second spacing being narrower than the first spacing.

19. The computer program product of claim 18, wherein the operations further comprise:
calculating the effective spacing for each physical spacing between two or more neighbor wires of a target wire of a putative design of an integrated circuit;
determining segment boundaries based on the calculated effective spacing to define the segments for the target wire;
selecting one of the segments;
identifying a metal configuration for the selected segment;
accessing a table of capacitance per-unit-length for the identified metal configuration to return an above capacitance value, a below capacitance value, a left-side capacitance value, and a right-side capacitance value for the corresponding segment;
scaling the above capacitance value, the below capacitance value, the left-side capacitance value, and the right-side capacitance value based on a corresponding segment length determined from the calculated effective spacing;
assessing an impact of the scaled capacitance values on circuit performance; and
in response to the assessment of impact on the circuit performance, producing a modified design by modifying the putative design of the integrated circuit.

20. The computer program product of claim 19, wherein the operations further comprise repeating the selecting, identifying, accessing and scaling operations for each remaining segment of the target wire.
